(19) United States
(12) Patent Application Publication
(10) Pub. No.: US 2006/0088966 A1
(43) Pub. Date: Apr. 27, 2006

(54) Semiconductor device having a smooth EPI layer and a method for its manufacture

(75) Inventors: Pang-Yen Tsai, Jhu-bei City (TW); Chie-Chien Chang, Chu-Tung (TW); Tze-Liang Lee, Hsinchu (TW); Shih-Chang Chen, Hsin-Chu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/970,339

(22) Filed: Oct. 21, 2004

(51) Int. Cl. H01L 21/336

(52) U.S. Cl. 438/285

(57) ABSTRACT

Provided are a semiconductor device and a method for manufacturing such a device by varying the pressure used to form silicon-germanium (SiGe) layers on a substrate such that a first layer is formed at a substantially higher pressure than a second layer that is formed on the first layer.

### CROSS-REFERENCE

This application is related to U.S. patent application (TSMC docket no. 2003-0591), filed on (not yet known), and entitled “EPITAXY LAYER AND METHOD OF FORMING THE SAME.”

### BACKGROUND

An integrated circuit (IC) is formed by creating one or more devices (e.g., circuit components) on a semiconductor substrate using a fabrication process. As fabrication processes and materials improve, semiconductor device geometries have continued to decrease in size since such devices were first introduced several decades ago. For example, current fabrication processes are producing devices having geometry sizes (e.g., the smallest component (or line) that may be created using the process) of 90 nm and below. However, the reduction in size of device geometries frequently introduces new challenges that need to be overcome. For example, certain surface layer parameters (e.g., smoothness or consistency) may be increasingly important as device geometries decrease. Accordingly, what is needed is a method for manufacturing a semiconductor device that addresses some of these challenges.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of an exemplary method for creating a smooth epi layer during semiconductor device manufacturing.

FIG. 2 illustrates one embodiment of at least one step of a semiconductor device being manufactured using the method of FIG. 1.

FIG. 3 illustrates the device of FIG. 2 undergoing another step of the method of FIG. 1.

FIG. 4 illustrates the device of FIG. 3 undergoing yet another manufacturing step.

### DETAILED DESCRIPTION

This disclosure relates generally to semiconductor manufacturing and, more particularly, to manufacturing a semiconductor device having a smooth epi layer.

It is understood, however, that the following disclosure provides many different embodiments or examples. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

Silicon-germanium (Si₁₋ₓGeₓ) is used in the advanced manufacturing of integrated circuits because, among other benefits, it may be used to produce strain in the channel area to enhance device performance. To achieve the maximum enhancement, the SiGe EPI layer needs to be lattice-matched to the silicon substrate. This lattice-matched EPI layer is fully stressed due to the fact that a Ge atom is larger than a Si atom. Therefore, the higher the Ge concentration, the larger the stress and the higher the device enhancement. However, such a highly stressed EPI layer is difficult to grow. For example, surface contamination or damage from pre-EPI processes may result in no growth or an island formation of SiGe (e.g., a discontinuous EPI layer). No device gain can be obtained with a no growth or islanding condition. In order to have a robust EPI process, higher deposition pressure (compared to a general process pressure at 10˜20 torr for selective EPI) may be used at the initial stage of the EPI growth. Such a higher pressure process shows better nucleation than lower pressure processes but with a slower deposition rate. With a good nucleation layer, subsequent EPI layers can be deposited at a lower pressure which is known to have a better pattern loading effect than higher pressure processes. In addition, the deposition rate can be tuned to favor wafer throughput.

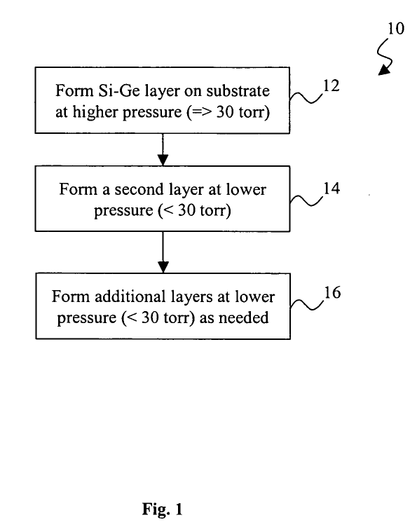

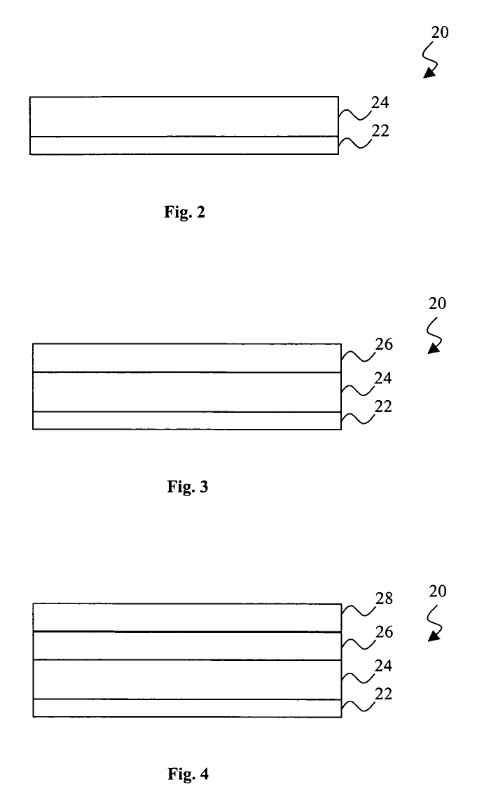

Referring now to FIG. 1, illustrated is one embodiment of a method 10 for manufacturing a semiconductor device on a semiconductor substrate using Si₍₁₋ₓ₎Geₓ. The following description makes reference to FIGS. 2 and 3, which illustrate one possible embodiment of a semiconductor device 20 undergoing various manufacturing steps using the method 10 of FIG. 1.

The device 20 includes a semiconductor substrate 22 that may comprise an elementary semiconductor such as crystal silicon, polycrystalline silicon, amorphous silicon, germanium and diamond, a compound semiconductor such as SiC, GaAs, AlP, AlAs, AlSb, GaP, GaSb, InP, InAs, and InSb, or an alloy semiconductor such as SiGe, GaAsP, AlInAs, AlGaAs, or GaInP. Furthermore, the semiconductor substrate 22 may be a semiconductor on insulator, such as silicon on insulator (SOI), or a thin film transistor (TFT). In one example, the semiconductor substrate 22 may include a doped epi layer or a buried layer. In another example, a compound semiconductor substrate may be used and may further include a multiple silicon structure. In still another example, the semiconductor substrate 22 may be a silicon substrate and may further include a multilayer compound semiconductor structure. The semiconductor substrate may contain doped regions, patterned areas, devices, and circuits, such as bipolar transistors, metal-oxide-semiconductor field effect transistors (MOSFETs), and BiCMOS (Bipolar and CMOS transistors).

In step 12 of FIG. 1 and with additional reference to FIG. 2, an SiGe layer 24 is formed on the substrate 22 at a relatively higher pressure (compared to a general process pressure of 10˜20 torr for EPI), such as greater than or equal to about 30 torr, in order to form a substantially smooth or planar buffer layer. The higher pressure may be achieved by containing the formation process within a reaction chamber, as is known in the art, to provide uniform nucleation and growth. The layer 24 may be an epitaxial (epi) layer formed using epitaxy growth (e.g., selective epitaxy, epitaxy by chemical vapor deposition (CVD), or molecular beam epitaxy (MBE)) using process gases (e.g., precursors, carriers, and etchers) such as SiH₂Cl₂, GeH₄, B₂H₆, HCl, and H₂ with a temperature between about 500° C. and 900° C. over a time period of approximately 10 seconds to 10 minutes. The layer 24 may have a thickness between approximately 5 and 200 Angstroms and, in the present example, has a germanium content of between approximately 10% and 50%. It is understood that other embodiments may have other levels of germanium concentration, such as between 2% and 60%.

In step 14 of FIG. 1 and with additional reference to FIG. 3, another SiGe layer 26 may be formed on the layer 24. The layer 26 conforms to the substantially smooth or planar surface of the layer 24, and so may itself be relatively smooth. The formation of the layer 26 occurs at a lower pressure than the layer 24 (e.g., less than 30 torr). The layer 26 may be formed at a temperature between about 500° C. and 900° C. over a time period of approximately 30 seconds to 60 minutes, and may have a thickness between approximately 50 and 2000 Angstroms. The germanium content of the layer 26 may be similar to that of the layer 24 (e.g., 10-50%), or may be higher or lower.

The formation of the layer 26 also occurs in a reaction chamber, but occurs at lower pressure which favors a better pattern loading effect. Process conditions can be tuned for higher throughput since a nucleation or buffer layer has already formed (layer 24). The decreased time needed to form the additional layer may allow benefits such as increased productivity in processing.

With additional reference to FIG. 4, additional layers 28 (illustrated as a single layer) may be formed on the layer 26 using the same pressure as that used in the formation of the layer 26 (e.g., less than 30 torr).

The method 10 allows for layers of varying concentration of germanium to be formed. Accordingly, the resulting structure formed by the SiGe layers 24, 26, and 28 may have a substantially homogenous germanium content throughout, may be graded (i.e., may have an increasing or decreasing level of germanium content), or may have alternating layers of various germanium concentrations. The high pressure formation process used to form the layer 24 enables the creation of a buffer layer with the same germanium content as the upper layers, and negates the need to use a concentration graded approach with a buffer layer having a lower concentration of germanium followed by upper layers having higher levels of germanium. Therefore, a higher stress level can be obtained with constant Ge stacks than with graded Ge plus constant Ge stacks.

It is understood that the SiGe layers described may be used for many different purposes. For example, in one embodiment, the SiGe layers may be epitaxially deposited to form a base for a high-performance transistor structure such as a Heterojunction Bipolar Transistor, or other devices that take advantage of different semiconductor bandgaps. In another embodiment, the SiGe layer may be used as a stressor at source and drain areas to create strain in the device channel area. In yet another embodiment, the SiGe layers may be used to form a strained Si layer or SiGe layer to act as a channel in complementary metal oxide semiconductor (CMOS) technologies.

Accordingly, in one embodiment, a method for manufacturing a semiconductor device comprises forming a first SiGe layer over a silicon substrate using a pressure greater than approximately 30 torr, and forming a second SiGe layer directly over the first SiGe layer using a pressure that is less than approximately 30 torr.

In another embodiment, a method for manufacturing a semiconductor device is provided. The method includes varying the pressure used to form SiGe layers on a substrate such that a first layer is formed at a substantially higher pressure than a second layer that is formed on the first layer, and forming a plurality of SiGe layers above the second layer using a pressure substantially similar to that used for the formation of the second layer.

In still another embodiment, a semiconductor device comprises a substrate formed at least partially from silicon, and first and second SiGe layers. The first SiGe layer is formed on the substrate, and the second SiGe layer is formed on the first SiGe layer. The first and second SiGe layers have a substantially similar concentration of germanium.

While the preceding description shows and describes one or more embodiments, it will be understood by those skilled in the art that various changes in form and detail may be made therein without departing from the spirit and scope of the present disclosure. For example, various steps of the described methods may be executed in a different order or executed sequentially, combined, further divided, replaced with alternate steps, or removed entirely. In addition, various functions illustrated in the methods or described elsewhere in the disclosure may be combined to provide additional and/or alternate functions. Therefore, the claims should be interpreted in a broad manner, consistent with the present disclosure.

What is claimed is:

1. A method for manufacturing a semiconductor device, the method comprising:
forming a first silicon-germanium (SiGe) layer over a silicon substrate using a pressure greater than approximately 30 torr; and
forming a second SiGe layer directly over the first SiGe layer using a pressure that is less than approximately 30 torr.

2. The method of claim 1 wherein the first and second SiGe layers have approximately the same concentration of Ge.

3. The method of claim 2 wherein the first SiGe layer has a germanium content between approximately 10% and 50%.

4. The method of claim 1 further comprising forming a third SiGe layer over the second SiGe layer, wherein the third SiGe layer has a higher concentration of Ge than the first and second layers.

5. The method of claim 1 wherein the first SiGe layer is formed using a temperature between about 500° C. and 900° C.

6. The method of claim 1 wherein the first SiGe layer is formed having a thickness between about 5 Å and 200 Å.

7. The method of claim 6 wherein the second SiGe layer is formed having a thickness between about 50 Å and 2000 Å.

8. The method of claim 1 wherein the first SiGe layer is substantially planar after being formed.

9. The method of claim 1 wherein forming the first SiGe layer includes using at least one of SiH₂Cl₂, GeH₄, B₂H₆, HCl, and H₂ as a process gas.

10. A method for manufacturing a semiconductor device, the method comprising:
varying the pressure used to form silicon-germanium (SiGe) layers on a substrate such that a first layer is formed at a substantially higher pressure than a second layer that is formed on the first layer; and
forming a plurality of SiGe layers above the second layer using a pressure substantially similar to that used for the formation of the second layer.

11. The method of claim 10 wherein the first layer is formed at a pressure greater than 30 torr.

12. The method of claim 11 wherein the second layer is formed at a pressure less than 30 torr.

13. A semiconductor device comprising:
a substrate formed at least partially from silicon;
a first silicon-germanium (SiGe) layer formed on the substrate; and
a second SiGe layer formed on the first SiGe layer, wherein the first and second SiGe layers have a substantially similar concentration of germanium.

14. The semiconductor device of claim 13 further comprising a plurality of additional SiGe layers formed on the second SiGe layer.

15. The semiconductor device of claim 13 wherein the first SiGe layer has a concentration of germanium between about 10% and 50%.

16. The semiconductor device of claim 15 wherein the second SiGe layer has a concentration of germanium substantially similar to that of the first SiGe layer.

17. The semiconductor device of claim 16 wherein the plurality of additional SiGe layers have a concentration of germanium substantially similar to that of the first SiGe layer.

18. The semiconductor device of claim 13 wherein the plurality of additional SiGe layers have concentrations of germanium substantially different from that of the first and second SiGe layers and each other.

19. The semiconductor device of claim 13 wherein the first SiGe layer forms a substantially planar surface.

20. The semiconductor device of claim 13 wherein the first SiGe layer has a thickness between about 5 Å and 200 Å.

21. The semiconductor device of claim 20 wherein the second SiGe layer has a thickness between about 50 Å and 2000 Å.

22. The semiconductor device of claim 13 wherein the device is a complementary metal oxide semiconductor (CMOS) device.
